(19) United States
(12) Patent Application Publication
(10) Pub. No.: US 2026/0309319 A1
(43) Pub. Date: Oct. 8, 2026

(54) COMPOSITE PRINTED CIRCUIT BOARD APPARATUS

(71) Applicant: WHELEN ENGINEERING COMPANY, INC., Chester, CT (US)

(72) Inventor: David J. Sousa, Ivoryton, CT (US)

(73) Assignee: WHELEN ENGINEERING COMPANY, INC., Chester, CT (US)

(21) Appl. No.: 19/638,551

(22) Filed: Apr. 3, 2026

Related U.S. Application Data
(60) Provisional application No. 63/784,182, filed on Apr. 6, 2025.

(51) Int. Cl. F21V 23/02; F21V 29/508; F21V 29/70; F21Y 115/10

(52) U.S. Cl. CPC F21V 23/02; F21V 29/508; F21V 29/70; F21Y 2115/10

(57) ABSTRACT

An apparatus includes a single-layer metal core printed circuit board (PCB) and a multi-layer power PCB. The single-layer metal core PCB is connected to the multi-layer power PCB via one or more soldering joints and one or more connecting elements. The single-layer metal core PCB includes one or more light emitting diodes (LEDs) that, once connected with the multi-layer power PCB, are operated by an electrical signal.

### CROSS-REFERENCE TO RELATED APPLICATION(S)

This application is related to and claims the benefit of priority from U.S. Provisional Application No. 63/784,182, titled “COMPOSITE PRINTED CIRCUIT BOARD APPARATUS,” filed on Apr. 6, 2025, the full disclosure of which is hereby incorporated by reference in its entirety for all purposes.

### BACKGROUND

### 1. Field of Disclosure

Embodiments of disclosure relates to a composite apparatus including a single layer metal core printed circuit board (PCB) and a multi-layer power PCB.

### 2. Description of Related Art

Many consumers want to have the brightest light emitting diode (LED) light source in the smallest possible package. Driving the LEDs at higher currents may result in a greater light output, but it also requires that the package dissipate more heat. To address heat generation, metal core PCBs are commonly used to provide very low thermal resistance between the LED heat source and the package heat sink. These metal core PCBs typically include a single conducting layer of copper laminated onto an aluminum metal core with a thin dielectric between the copper and metal core. In other attempts to lessen waste heat, switching current regulators may be used. These switching current regulators may minimize the heat produced by the regulator circuits allowing the package to run cooler. However, these switching regulators operate at high frequencies and may be a source for both conducted and radiated radio frequency (RF) emissions. In some instances, a solution to the emission problem is to use multi-layer PCBs to minimize the high current loops which may cause RF emissions. Thus, there are conflicting engineering requirements: a single layer, metal core PCB to dissipate heat, and a multi-layer PCB to reduce RF emissions. Multi-layer metal core PCBs are available, but they are expensive, and their thermal performance is inferior to single layer metal core PCBs.

### SUMMARY

In an embodiment, a composite circuit assembly includes a multi-layer power printed circuit board (PCB) having a first top side and a first bottom side. The multi-layer power PCB further includes a switching current regulator to provide power conversion, the switching current regulator including an integrated power supply controller, a power inductor, and a switching field-effect transistor (FET). The multi-layer power PCB additionally includes one or more first soldering pads on the first bottom side. The composite circuit assembly also includes a single-layer metal core PCB having a second top side and a second bottom side. The single-layer metal core PCB further includes one or more light-emitting diodes mounted on the second top side, one or more second soldering pads on the second top side, further to align with the first soldering pads on the first bottom side of the multi-layer power PCB, and one or more connecting elections to connect the multi-layer power PCB to the single-layer metal core PCB.

In another embodiment, a method for dissipating heat includes providing a single-layer metal core printed circuit board (PCB) having a first top side and first bottom side, the single-layer metal core PCB further including one or more light-emitting diodes (LEDs) mounted on the first top side and one or more thermal pads on the first top side. The method also includes providing a multi-layer power PCB having a second top side and a second bottom side, the multi-layer power PCB further including one or more thermal pads on the second bottom side. The method additionally includes thermally coupling the single-layer metal core PCB to the multi-layer power PCB by heating the thermal pads.

In yet another embodiment, a composite apparatus includes a single-layer metal core printed circuit board (PCB) having a top side and a bottom side, the single-layer metal core PCB further having one or more light-emitting diodes (LEDs) mounted on the top side. The composite apparatus also includes a multi-layer power PCB mounted on the top side of the single-layer metal core PCB, the multi-layer power PCB including one or more heat generating elements. In the composite apparatus, the multi-layer power PCB is mounted to the single-layer metal core PCB via one or more thermal pads having soldering elements.

### BRIEF DESCRIPTION OF THE DRAWINGS

Various features of the aspects described herein are set forth with particularity in the appended claims. The various aspects, however, both as to organization and methods of operation, together with advantages thereof, may be understood in accordance with the following description taken in conjunction with the accompanying drawings as follows:

FIG. 1A illustrates a top side of a single-layer metal core PCB, according to example embodiments;

FIG. 1B illustrates a top side and a bottom side of a multi-layer power core PCB, according to example embodiments;

FIG. 1C illustrates a composite of the single-layer metal core PCB and a multi-layer power core PCB, according to example embodiments;

FIG. 1D illustrates a cross-sectional perspective of a composite of the single-layer metal core PCB and a multi-layer power core PCB, according to example embodiments;

FIG. 2 illustrates a composite of the single-layer metal core PCB and a multi-layer power core PCB removably attached to a heat sink, according to example embodiments;

FIG. 3 illustrates a system for transmitting a signal to the composite of the single-layer metal core PCB and a multi-layer power core PCB to operate one or more light emitting diodes (LEDs), according to example embodiments;

FIG. 4A illustrates a method for coupling a single-layer metal core PCB to a multi-layer power PCB, according to example embodiments;

FIG. 4B illustrates a method for attaching a composite of the single-layer metal core PCB and a multi-layer power core PCB to a heat sink to dissipate heat, according to example embodiments; and

FIG. 4C illustrates a method for adjusting the lighting of LEDs on the composite of the single-layer metal core PCB and a multi-layer power core PCB based on a signal from a controller, according to example embodiments.

### DETAILED DESCRIPTION

The foregoing aspects, features, and advantages of the present disclosure will be further appreciated when considered with reference to the following description of embodiments and accompanying drawings. In describing the embodiments of the disclosure illustrated in the appended drawings, specific terminology will be used for the sake of clarity. However, the disclosure is not intended to be limited to the specific terms used, and it is to be understood that each specific term includes equivalents that operate in a similar manner to accomplish a similar purpose. Additionally, like reference numerals may be used for like components, but such use should not be interpreted as limiting the disclosure.

When introducing elements of various embodiments of the present disclosure, the articles “a”, “an”, “the”, and “said” are intended to mean that there are one or more of the elements. The terms “comprising”, “including”, and “having” are intended to be inclusive and mean that there may be additional elements other than the listed elements. Any examples of operating parameters and/or environmental conditions are not exclusive of other parameters/conditions of the disclosed embodiments. Additionally, it should be understood that references to “one embodiment”, “an embodiment”, “certain embodiments”, or “other embodiments” of the present disclosure are not intended to be interpreted as excluding the existence of additional embodiments that also incorporate the recited features. Furthermore, reference to terms such as “above”, “below”, “upper”, “lower”, “side”, “front”, “back”, or other terms regarding orientation or direction are made with reference to the illustrated embodiments and are not intended to be limiting or exclude other orientations or directions. Moreover, references to “substantially” or “approximately” or “about” may refer to differences within ranges of +/-10 percent. Furthermore, like numbers may be used to refer to like elements throughout, but it should be appreciated that using like numbers is for convenience and clarity and not intended to limit embodiments of the present disclosure. For example, one or more subsequent figures may share similar features with one or more prior figures and the similar features may be identified with like reference numerals for convenience purposes only and not to limit the scope of the present disclosure.

The present disclosure describes a composite apparatus including a single-layer metal core printed circuit board (PCB) (hereinafter metal core PCB) and a multi-layer power PCB (hereinafter power PCB). The metal core PCB may include multiple LEDs mounted on its surface. On the same surface, the metal core PCB may include one or more soldering joints and mating holes. These soldering joints and mating holes are configured to connect the metal core PCB with the power PCB. The power PCB contains the processing and power elements to operate the LEDs on the metal core PCB. Once the metal core PCB is in electrical and mechanical connection with the power PCB, the power PCB may operate the LEDs on the metal core PCB. Furthermore, the heat generated from elements on the PCB (e.g., CPUs, GPUs, power elements, etc.) may be dissipated by the metal core of the metal core PCB. In other embodiments, once the metal core PCB and the power PCB are connected, they may be connected to a heat sink to further dissipate heat. In still other embodiments, the power PCB may receive signals from a controller which operate aspects of the LEDs on the metal core PCB. The composite apparatus including the metal core PCB and the power PCB may be used in a variety of environments including, without limitation, vehicles (e.g., lighting apparatuses for emergency vehicles) and other industrial settings. By combining the single-layer metal core PCB with the multi-layer power PCB, the composite apparatus offers both adequate heat dissipation (via the metal layer of the metal core PCB) and reduction of RF (via the multiple layers of the multi-layer power PCBs).

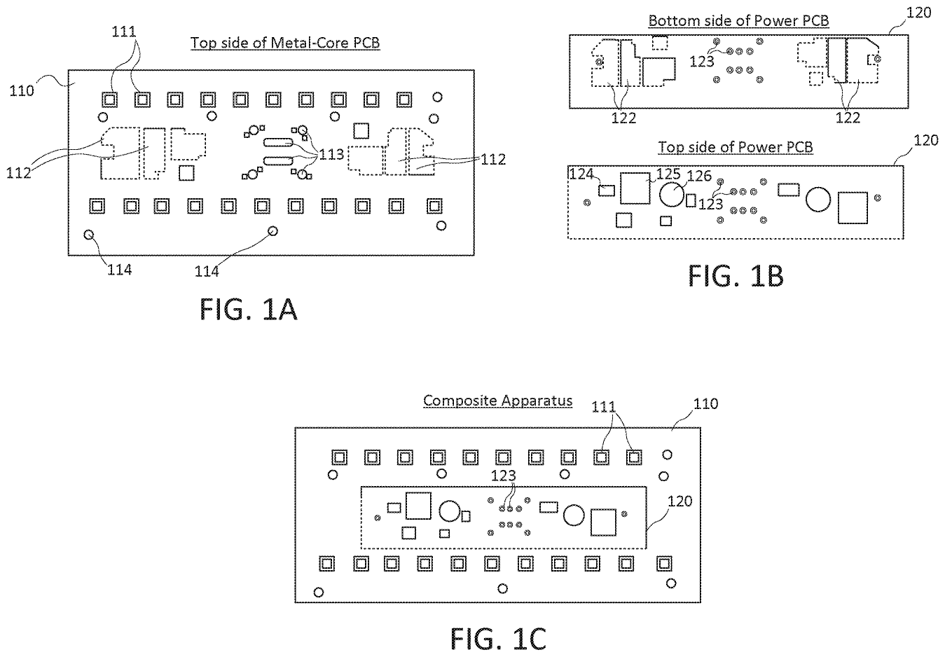

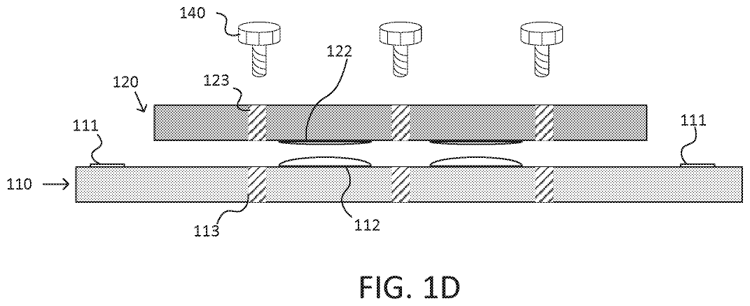

FIGS. 1A-1D illustrate a metal core PCB 110 and a power PCB 120 according to example embodiments.

FIG. 1A illustrates a metal core PCB 110 including one or more light emitting diodes (LEDs) 111, one or more soldering pads 112, and one or more mating holes 113 and 114. Generally, the metal core PCB 110 may comprise a top side and a bottom side, with the elements described herein with reference to FIG. 1A being on the top side. The metal core PCB 110 may include a PCB that has metal at its core layer, unlike some conventional PCBs which use, e.g., fiberglass. In some example embodiments, the metal core of the metal core PCB 110 may include aluminum, copper, steel, or some composite metal. The metal core of the metal core PCB 110 may dissipate heat away from one or more heat-generating components on the power PCB 120 once the metal core PCB 110 is connected to the power PCB 120. That is, the metal core may conduct heat away from heat-generating components (e.g., CPUs, GPUs, and power elements), reduce the risk of thermal damage of the power PCB 120, and extend the life of the heat-generating components. In some embodiments, the metal core PCB 110 may also include a dielectric layer for separating the metal from a copper circuit layer.

The LEDs 111 may include semiconductor devices that emit light when an electric current passes through them. The LEDs 111 may be mounted to the top side of the metal core PCB 110 using one or more connecting elements such as, without limitation, solder pads, adhesives, or any other suitable connecting element. The LEDs 111 may be turned on or off, or they may have their brightness adjusted by an electrical signal (e.g., voltage and current) sent to their terminals. As discussed elsewhere herein, the LEDs 111 may be operated by the power elements on the power PCB 120.

The soldering pads 112 may include small metal surfaces on the metal core PCB 110 designed to create electrical and mechanical connections between the metal core PCB 110 and the power PCB 120. In some example embodiments, the soldering pads 112 may be comprised of copper and some coating or surface finishes. The soldering pads 112 may correspond to the connecting pads 122, which themselves may or may not include soldering material. In various example embodiments, the soldering pads 112 and the connecting pads 122 may be connected by one or more soldering strategies such as reflow soldering or hand soldering. In some embodiments, the soldering pads 112 are heated using a soldering iron or reflow oven until the soldering material on the soldering pads 112 melts and flows onto the connecting pads 122. Once the soldering material hardens, it creates a solid electrical and mechanical connection between the metal core PCB 110 and the power PCB 120.

The mating holes 113 and 114 may be positioned at various portions of the metal core PCB 110, such as, without limitation, in a central position, offset from one or more sides, or indeed at any position on the metal core PCB 110. Although FIG. 1A illustrates only a certain number of mating holes 113 and 114, other embodiments may include a greater or fewer number of mating holes 113 and 114, as well as mating holes 113 and 114 on different portions of the metal core PCB 110 than those illustrated in FIG. 1A.

FIG. 1B illustrates a power PCB 120 with a top side and a bottom side. The bottom side of the power PCB 120 may include one or more connecting pads 122 and one or more mating holes 123. The connecting pads 122 may correspond to the one or more soldering pads 112 on the metal core PCB 110. The mating holes 123 may correspond to the one or more mating holes 113 and 114 on the metal core PCB 110. When a user is preparing to connect the metal core PCB 110 to the power PCB 120, the mating holes 123 may be configured to align with the mating holes 113 and 114 of the metal core PCB. In example embodiments, one or more surface-mount (SMT) standoffs may be threaded through the mating holes 123, 113, and/or 114 to further connect the metal core PCB 110 and power PCB 120, with further reference to FIG. 1D. The top side of the power PCB 120 may also include the one or more various computing and power elements 124, 125, and 126. Elements 124-126 may include, without limitation, a switching current regulator comprising an integrated power supply controller, a power inductor, and a switching field-effect transistor (FET). The power supply controller may generate one or more control signals to regulate the switching transistor and adjust a duty cycle to maintain a desired output voltage. In some example embodiments, the power supply controller may connect to a power input, the switching FET, and feedback components to monitor and adjust the voltage. The power inductor may store and release energy in response to the switching action of the transistor. The FET may act as a switch that controls the charging and discharging of the power inductor. Furthermore, the power PCB 120 may include one or more other heat-generating elements such as CPUs, GPUs, SSDs, power elements, and other similar elements. Generally, the switching current regulator may reduce the heat produced by the computing and power elements on the power PCB 120. The switching current regulator may operate at high frequencies and may be a source for both conducted and radiated RF emissions. However, the multiple layers of the power PCB 120 may minimize the high current loops which may otherwise cause RF emissions.

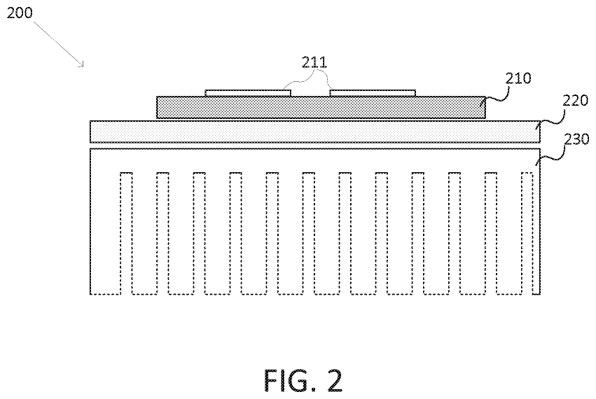

FIG. 1C illustrates a composite apparatus. The power PCB 120 may be aligned and connected with the metal core PCB 110 to make the composite apparatus. In example embodiments, the power PCB 120 may include one or SMT standoffs which may be received by the one or more mating holes 123 and 113. Furthermore, the soldering pads 112 may be heated to a low viscosity, then the connecting pads 122 may be placed on the soldering pads 112. When the soldering pads 112 have cooled, an electrical and mechanical connection may be established between the metal core PCB 110 and the power PCB 120. Once the metal core PCB 110 and the power PCB 120 are connected, the power PCB 120 may operate with the one or more LEDs 111. Furthermore, as the power PCB 120 operates, the metal core of the metal core PCB 110 may dissipate heat from the heat-generating components of the power PCB 120. As discussed elsewhere herein with further reference to FIG. 2, the composite apparatus may, in some example embodiments, connect to one or more internal or external power sources.

FIG. 1D illustrates a cross-sectional side perspective view of the power PCB 120 and the metal core PCB 110. In example embodiments, the power PCB 120 may be placed on top of the metal core PCB 110 so that the mating holes 123 align with the mating holes 113, thereby allowing one or more connecting elements 140 to be threaded through the mating holes 123 and 113. The connecting elements 140 may include, without limitation, SMT standoffs, screws, fasteners, bolts, or other suitable connecting elements. The bottom side of the power PCB 120 may include one or more connecting pads 122 to align with the soldering pads 112 on the metal core PCB 110. The connecting pads 122 may themselves include soldering material, although in other example embodiments, the connecting pads 122 may be bare spots on the surface of the power PCB 120, or they may be solder mask defined pads (SMD pads) which may define where the connection will form. In some example embodiments, the connecting pads 122 may conduct thermal energy from the one or more heat-generating elements on the power PCB 120. The power PCB 120 may be connected to the metal core PCB 110 such that the power PCB 120 is in a central region of the metal core PCB 110, wherein the central region is surrounded by one or more LEDs 111.

FIG. 2 illustrates an apparatus 200 in which the power PCB 210 has been connected to the metal core PCB 220 as discussed with further reference to FIGS. 1A-1D. The composite apparatus including the power PCB 210 and the metal core PCB 220 may be connected to a heat sink 230 to provide further heat dissipation from one or more heat generating elements on both or either the power PCB 210 and the metal core PCB 220, such as heat generating elements 211 or LEDs on the metal core PCB 220. Generally, the heat sink 230 may include a passive or active cooling device which dissipates heat from heat generating components on either or both the metal core PCB 220 and power PCB 210. As illustrated in FIG. 2, the heat sink 230 may be a finned heat sink including one or more metal fins which allow heat to dissipate into the surrounding air more efficiently. In other example embodiments, the heat sink 230 may include a cooling fan, cold plate, or heat pipe system.

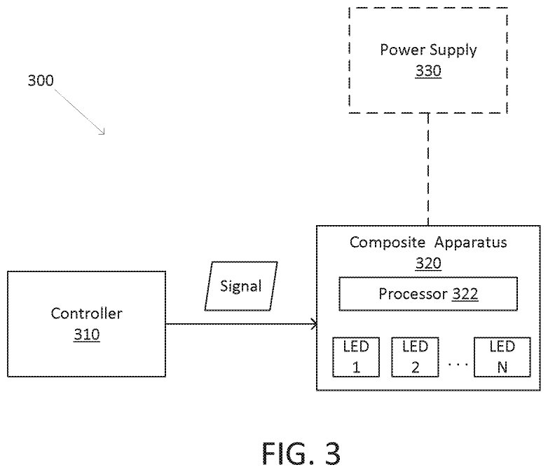

FIG. 3 illustrates a system 300 for sending signals to the composite apparatus 320. The system 300 may include a controller 310, a composite apparatus 320, and a power supply 330. The composite apparatus 320 may include the metal core PCB and power PCB electrically and mechanically connected together by one or more soldering joints as discussed with further reference to FIGS. 1A-1D. The composite apparatus 320 may include a processor 322, which itself may include a CPU, GPU, or other similar processor on the power PCB. The composite apparatus 320 may further include multiple LEDs, such as LED 1, LED 2, up to any number of LEDs, N. Each of the LEDs may be activated by an electrical signal. As a nonlimiting example, the controller 310 may transmit a signal over a wired or wireless connection to the composite apparatus 320, which may in turn, via the processor 322, communicate the signal to the LEDs. In some example embodiments, the signal may turn the LEDs on or off, or adjust the brightness of the LEDs. In other example embodiments, the composite apparatus 320 may be powered by either an internal power unit (e.g., a battery) or by an external power source, such as the power supply 330 which may be connected to the composite apparatus 320 by any type of wired connection.

The controller 310 may include one or more processors of any type deemed suitable by those of skill in the relevant art, some examples including a general-purpose microprocessor and a dedicated digital signal processor (DSP). The controller 310 may include one or more microprocessors, one or more microchips, one or more ASICs, one or more FPGAs, one or more GPUs, one or more TPUs, and/or one or more processing devices and/or processing components of any other type.

Similarly, the processor 322 may include one or more processors of any type deemed suitable by those of skill in the relevant art, some examples including a general-purpose microprocessor and a dedicated digital signal processor (DSP). The processor 322 may include one or more microprocessors, one or more microchips, one or more ASICs, one or more FPGAs, one or more GPUs, one or more TPUs, and/or one or more processing devices and/or processing components of any other type.

The signal sent by the controller 310 may include a wired or wireless signal. In example embodiments, a wired signal may include a voltage or current change such as a pulse width modulation (PWM), digital on/off control, or an analog voltage level. A wireless signal might include a radio frequency (RF), Bluetooth, or CAN bus connection.

The power supply 330 may include, without limitation, a vehicle battery, an external power supply, or a rechargeable battery pack. The power supply 330 may be connected to the composite apparatus 320 by one or more wires, connectors, or terminal blocks.

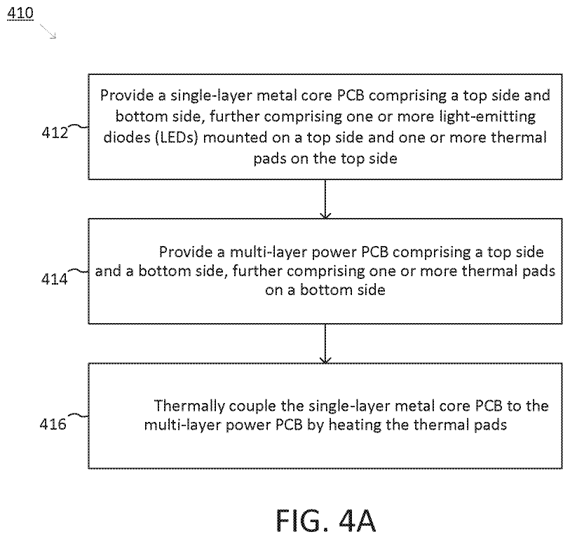

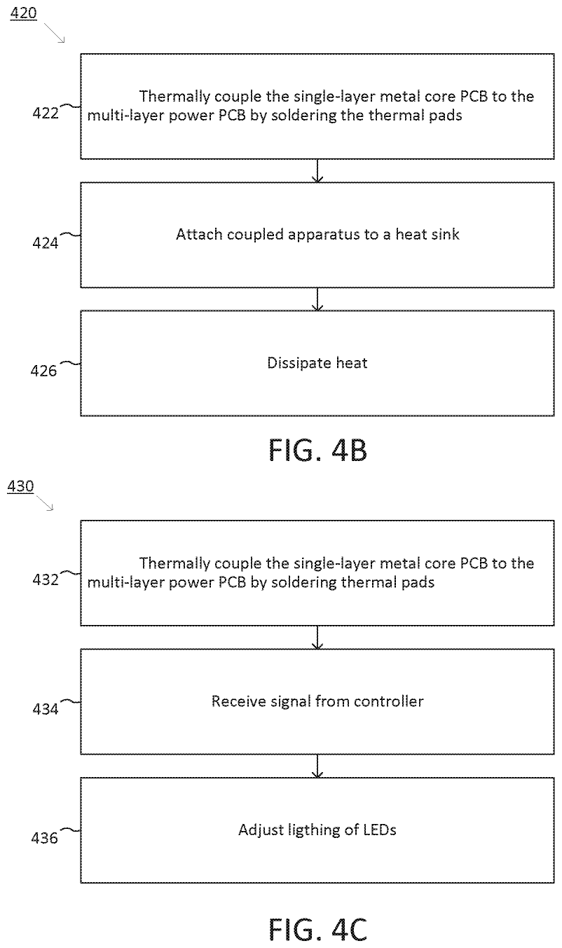

FIG. 4A illustrates a method 410 for connecting a metal core PCB to a power PCB. The method 410 may be done in a greater or fewer number of steps than illustrated in FIG. 4A, and in other embodiments, the method 410 may be performed in a different order than what is illustrated. A single-layer metal core PCB may be provided 412, wherein the single-layer metal core PCB comprises a top side and a bottom side, and further comprises one or more LEDs mounted on the top side. Furthermore, the top side of the single-layer metal core PCB may include one or more thermal pads such as soldering pads. A multi-layer power PCB may be provided 414, wherein the multi-layer PCB comprises a top side and a bottom side, the bottom side comprising one or more thermal pads such as connecting pads. The single-layer metal core PCB may be thermally coupled 416 to the multi-layer PCB by heating or melting the soldering material on either the single-layer metal core PCB or the multi-layer PCB, then pressing the single-layer metal core PCB and the multi-layer PCB together to establish an electrical and mechanical connection between the two. In other embodiments, the metal core PCB and the power PCB may be further connected by one or more connecting elements such as SMT standoffs, screws, bolts, fasteners, or other suitable connecting elements to be threaded through one or more aligning mating holes on the metal core PCB and the metal core PCB.

FIG. 4B illustrates a method 420 for attaching an apparatus comprising the single-layer metal core PCB and the multi-layer PCB to a heat sink. The method 420 may be done in a greater or fewer number of steps than illustrated in FIG. 4B, and in other embodiments, the method 420 may be performed in a different order than what is illustrated. The single-layer metal core PCB may be thermally coupled 422 to the multi-layer PCB by heating or melting the soldering material on either the single-layer metal core PCB or the multi-layer PCB, then pressing the single-layer metal core PCB and the multi-layer PCB together to establish an electrical and mechanical connection between the two. The apparatus may then be attached 424 to a heat sink, including a passive or active cooling device that dissipates heat 426 from heat generating components on either or both the single-layer metal core PCB and the multi-layer PCB. In some example embodiments, the heat sink may be a finned heat sink including one or more metal fins which allow heat to dissipate into the surrounding air more efficiently. In other example embodiments, the heat sink may include a cooling fan, cold plate, or heat pipe system.

FIG. 4C illustrates a method 430 for adjusting the lighting of the LEDs on the metal core PCB. The method 430 may be done in a greater or fewer number of steps than illustrated in FIG. 4C, and in other embodiments, the method 430 may be performed in a different order than what is illustrated. The single-layer metal core PCB may be thermally coupled 432 to the multi-layer PCB by heating or melting the soldering material on either the single-layer metal core PCB or the multi-layer PCB, then pressing the single-layer metal core PCB and the multi-layer PCB together to establish an electrical and mechanical connection between the two. The resulting composite apparatus may receive 434 a signal from a controller which has either or both a wireless and wired connection with the composite apparatus. As a nonlimiting example, the controller may transmit a signal over a wired or wireless connection to the composite apparatus, which may in turn, via a processor on the composite apparatus, communicate the signal to the LEDs on the metal core PCB. In some example embodiments, the signal may turn the LEDs on or off, or adjust 436 the brightness of the LEDs.

### Applications

In some example embodiments, the composite apparatus discussed herein may be integrated into emergency vehicle lighting and general vehicle lighting, providing a highly efficient and thermally managed solution for high intensity LED systems. For example, emergency lights require bright, reliable illumination, and the metal core PCB ensures that the LEDs operate at a sufficient brightness while also efficiently dissipating heat. The power PCB allows for synchronized flashing patterns, variable intensity, and integration with vehicle electrical systems. For general lighting, this technology could be applied to headlights, brake lights, and auxiliary lighting.

Beyond automotive applications, this system may be used in industrial and architectural lighting. In factories, warehouses, and outdoor spaces, high power LED systems require effective heat management to ensure consistent performance over long operating hours. The metal core PCB provides a reliable foundation for these applications, while the power PCB allows for smart lighting control including dimming, remote operation, and automated scheduling. By combining thermal efficiency with advanced control capabilities this composite apparatus could contribute to more sustainable and high performance lighting solutions across various industries.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A composite circuit assembly, comprising:
a multi-layer power printed circuit board (PCB) comprising a first top side and a first bottom side, the multi-layer power PCB further comprising:
a switching current regulator to provide power conversion, the switching current regulator comprising an integrated power supply controller, a power inductor, and a switching field-effect transistor (FET); and
one or more first soldering pads on the first bottom side; and
a single-layer metal core PCB comprising a second top side and a second bottom side, the single-layer metal core PCB further comprising:
one or more light-emitting diodes mounted on the second top side;
one or more second soldering pads on the second top side, further to align with the first soldering pads on the first bottom side of the multi-layer power PCB; and
one or more connecting elections to connect the multi-layer power PCB to the single-layer metal core PCB.

2. The composite circuit assembly of claim 1, wherein the first soldering pads and second soldering pads align to create a solder joint to provide electrical connectivity between the multi-layer power PCB and the single-layer metal core PCB.

3. The composite circuit assembly of claim 1, wherein the single-layer metal core PCB dissipates heat from one or more heat-generating components on the multi-layer power PCB and the single-layer metal core PCB.

4. The composite circuit assembly of claim 3, wherein the single-layer metal core PCB is thermally coupled to a heat sink to dissipate heat from at least one of the multi-layer power PCB or the single-layer metal core PCB.

5. The composite circuit assembly of claim 1, wherein the switching current regulator powers on the one or more LEDs.

6. The composite circuit assembly of claim 1, wherein the assembly is integrated into a vehicle lighting system.

7. The composite circuit assembly of claim 1, wherein the assembly is integrated into a lighting apparatus for general illumination.

8. The composite circuit assembly of claim 1, wherein the multi-layer power PCB receives one or more wireless or wired signals from a controller, the one or more wireless or wired signals to activate the LEDs.

9. The composite circuit assembly of claim 8, wherein the one or more wireless or wired signals further control a brightness of the one or more LEDs to one or more brightness levels.

10. A method for dissipating heat, comprising:
providing a single-layer metal core printed circuit board (PCB) comprising a first top side and first bottom side, the single-layer metal core PCB further comprising one or more light-emitting diodes (LEDs) mounted on the first top side and one or more thermal pads on the first top side;
providing a multi-layer power PCB comprising a second top side and a second bottom side, the multi-layer power PCB further comprising one or more thermal pads on the second bottom side; and
thermally coupling the single-layer metal core PCB to the multi-layer power PCB by heating the thermal pads.

11. The method of claim 10, further comprising:
attaching the single-layer metal core PCB to a heat sink to dissipate heat from the multi-layer power PCB.

12. The method of claim 10, further comprising:
activating or deactivating the LEDs via one or more wired or wireless signals from a controller.

13. The method of claim 10, further comprising:
mounting the thermally coupled single-layer metal core PCB and multi-layer power PCB onto a vehicle.

14. The method of claim 10, further comprising:
converting electrical power from a power supply controller in the multi-layer power PCB into a power output to the one or more LEDs.

15. The method of claim 10, further comprising:
dissipating heat from the multi-layer power PCB via the single-layer metal core PCB.

16. A composite apparatus, comprising:
a single-layer metal core printed circuit board (PCB) comprising a top side and a bottom side, the single-layer metal core PCB further comprising one or more light-emitting diodes (LEDs) mounted on the top side; and
a multi-layer power PCB mounted on the top side of the single-layer metal core PCB, the multi-layer power PCB comprising one or more heat generating elements;
wherein the multi-layer power PCB is mounted to the single-layer metal core PCB via one or more thermal pads comprising soldering elements.

17. The composite apparatus of claim 16, wherein the single-layer metal core PCB is removably attached to a heat sink to dissipate heat from the multi-layer power PCB.

18. The composite apparatus of claim 16, wherein thermal pads create a solder joint to provide electrical connectivity between the multi-layer power PCB and the single-layer metal core PCB.

19. The composite apparatus of claim 16, wherein the composite apparatus is mounted onto a vehicle.

20. The composite apparatus of claim 16, wherein the multi-layer power PCB receives one or more wireless or wired signals from a controller, the signals to activate and deactivate the one or more LEDs.
